(19) United States
(12) Patent Application Publication
(10) Pub. No.: US 2016/0359063 A1
(43) Pub. Date: Dec. 8, 2016

(54) CONICAL SOLAR CELL

(71) Applicant: Umm Al-Qura University, Makkah (SA)

(72) Inventor: Salem ALMUTAIRI, Makkah (SA)

(73) Assignee: Umm Al-Qura University, Makkah (SA)

(21) Appl. No.: 14/731,932

(22) Filed: Jun. 5, 2015

(51) Int. Cl. H01L 31/0352; H01L 31/0216; H01L 31/024; H01L 31/0368; H02S 40/10; H02S 40/42; H02S 20/32; H01L 31/0376

(52) U.S. Cl. CPC H01L 31/035281; H02S 20/32; H01L 31/02168; H01L 31/03762; H01L 31/03685; H02S 40/10; H02S 40/42; H01L 31/024

(57) ABSTRACT

A conical solar cell having a photo-responsive section in the form of a cone having a base, an apex, and a conical surface. The photo-responsive section includes a photoelectric conversion material disposed on the conical surface of the cone. The photoelectric conversion material is configured to absorb light and produce an electrical current. The conical solar cell has a first electrode and a second electrode connected to the photoelectric conversion material whereby photovoltaic energy is extractable from the photoelectric conversion material. The conical solar cell has an optional mounting base on which the cone is mounted. Optionally, the diameter of the cone at the base is less than a height of the cone as measured from a center point of the base to the apex of the cone.

### BACKGROUND OF THE INVENTION

Field of the Invention

The present invention is related to solar cells and solar cell arrays for the collection and conversion of solar energy into electrical energy, although the cells of the invention can be used for photoelectric conversion of non-solar light into electrical energy.

Description of the Related Art

Many configurations of solar energy collectors are known. For electricity conversion, one the most common configuration is that of a flat panel module having a number of photoelectric or photovoltaic cells, or solar cells (terms used interchangeably), encased within an enclosure having a transparent cover through which sunlight passes and impinges directly on a photoelectric material of the solar cell.

In this “flat panel” configuration, each solar cell is connected to electrical conductors which are brought to terminal connectors from which the electrical power may be taken. Typically, a number of these modules are electrically connected together, as a photovoltaic system to produce therefrom a desired power at a desired voltage level. The solar cell circuitry should be protected from the effects of the environment to which it is exposed, while at the same time having a transparent covering (typically including an anti-reflective coating) which permits light to pass through the transparent layer and be absorbed in the photoelectric material of the solar cell. Absorption of light in the solar cell produces electron-hole pairs which drift in opposite directions because of p-n junction in the material. The generation of electron-hole pairs and their spatial separation produces a photo-voltage across each cell

For terrestrial applications, the environment is harsh due to dust, rain, hail and other projectiles; a glass-like coating is preferred as the transparent coating, but glass-like coatings can be expensive and susceptible to breakage from impacts and thermal stresses. Polymer coverings are less expensive than glass and are more flexible but degrade in time due to ultraviolet radiation effects. For terrestrial applications, the environment also can inadvertently coat the solar cell with dirt and debris also serving as mechanism for performance degradation.

Optical-film technology has played an important role in the development of photovoltaic (PV) solar cells. As noted above, the top layer of the solar cell is typically a thin cover glass, coated with a conventional anti-reflection (AR) coating. Such AR coatings are generally considered important to the performance and environmental robustness of PV systems.

As far as the photoelectric material of the solar cell is concerned, exemplary photoelectric materials include materials such as for example crystalline silicon (c-Si), polycrystalline silicon, microcrystalline silicon, amorphous silicon (α-Si), copper indium gallium diselenide (CIGS), and various III-V compounds. A variety of single-junction (p-n junction) and multiple junction solar cells have been fabricated.

For amorphous silicon (α-Si) cells (considered attractive because of their relatively cheap cost), such cells are typically engineered not only with anti-reflection (AR) coating but also have an internal design which promotes the internal scattering of light within the cell structure to improve the likelihood that the light will be converted in the amorphous silicon photoelectric material before it exits the solar cell. While this effect is most pronounced for thin-film amorphous silicon (α-Si) cells, the problem of internal loss of light without photoelectric conversion exists for other cells as well (as detailed below).

Regardless of these measures, in operation due to the environmental factors noted above and/or the imperfect anti-reflection coatings and/or the internal loss of light before its absorption in the photoelectric material, a non-trivial amount of solar radiation is scattered or reflected by the flat panels and does not result in photoelectric conversion for that portion of light loss.

### SUMMARY OF THE INVENTION

In one embodiment of the present invention, there is provided a conical solar cell having a photo-responsive section in the form of a cone having a base, an apex, and a conical surface. The photo-responsive section includes a photoelectric conversion material disposed on the conical surface of the cone. The photoelectric conversion material is configured to absorb light and produce an electrical current. The conical solar cell has a first electrode and a second electrode connected to the photoelectric conversion material, whereby photovoltaic energy is extractable from the photoelectric conversion material. The conical solar cell has an optional mounting base on which the cone is mounted. Optionally, the diameter of the cone at the base is less than a height of the cone as measured from a center point of the base to the apex of the cone.

In one embodiment of the present invention, there is provided a solar cell platform including a base supporting one or more of the conical solar cells described above; and a controller programmed to at least one of 1) track an instantaneous position of the Sun in the sky, 2) rotate the conical solar cells each about a longitudinal axis thereof, and 3) adjust an inclination of the base to align the base with the instantaneous position of the Sun.

In one embodiment of the present invention, there is provided a method of producing photovoltaic power. The method provides a closed section structure with a longitudinal axis on a base supporting the closed section structure, exposes the closed section structure including a photoelectric conversion material to solar energy from the Sun, rotates the closed section structure on the longitudinal axis, and optionally, adjusts a position of the base to track the Sun angle.

It is to be understood that both the foregoing general description of the invention and the following detailed description are exemplary, but are not restrictive of the invention.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic depicting one conical solar cell unit;

FIG. 2 is a reproduction of Snell's law;

FIG. 3 is a schematic depicting a sectional view of cone unit at a mid-plane of the cone;

FIG. 4 is a schematic diagram showing a plurality of the cone units 2 forming a cell tower array 40.

FIG. 5A is a schematic depicting an amorphous silicon multi junction structure on a stainless steel substrate;

FIG. 5B is a schematic depicting the tracking of a solar cell tower with the sun;

FIG. 6 is a flowchart depicting an exemplary method of power generation; and

FIG. 7 is a schematic depicting a computer system for implementing various embodiments of the invention including that of operating the tracking system of FIG. 5B;

### DETAILED DESCRIPTION OF THE INVENTION

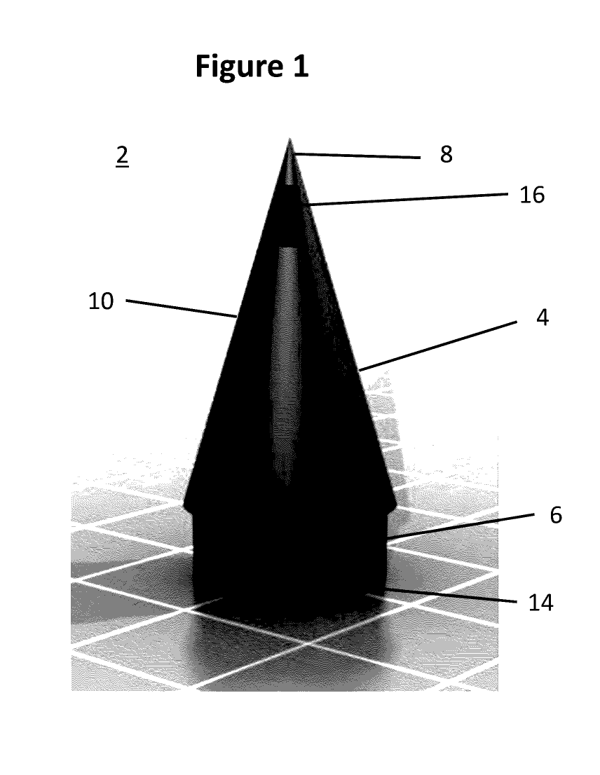

In this invention, the “flat” solar cell configuration is avoided by the use of the inventive conical design. FIG. 1 is a schematic depicting one conical solar cell unit 2. The conical solar cell 2 has photo-responsive section 4 in the form of a cone having a base 6, an apex 8, and a conical surface 10. A diameter of the cone at the base 6 can be less than a height of the cone as measured from a center point of the base 6 to the apex 8 of the cone. A photoelectric conversion material 12 (not shown in FIG. 1) is disposed on the conical surface 10 of the cone. The photoelectric conversion material 12 is configured to absorb light and produce an electrical current. The conical solar cell unit 2 has an electrode 14 connected to the photoelectric conversion material 12 (e.g. near base 6) and another electrode 16 connected near the photoelectric conversion material 12 (e.g., near apex 8), whereby photovoltaic energy is extractable from the photoelectric conversion material. The electrode position(s) depicted in FIG. 1 are purely pictorial and the exact positioning of these electrodes to extract power would depend on the details of the photovoltaic device structure employed.

The conical solar cell unit 2 of this invention has an optional mounting base 18 on which the solar cell unit 2 is mounted. In one embodiment of the invention, the conical solar cell unit 2 can rotate about its longitudinal axis. In this embodiment the electrodes 14, 16 would preferably be at the base and would make contact by a sliding contact such as an electrical brush.

Even though described in many embodiments here as a conical solar cell unit, there are embodiments of the invention which do not require the units to be comical. Other structures with curved external surfaces (capable of rotation about a longitudinal axis) could be used. While not preferred, even non-curved structural units could also be used.

In one embodiment of the invention, the conical solar cell unit 2 can be tilted to track the sun angle in the sky. In one embodiment, the conical sell units can rotate simultaneously with the tilting of base 18 to track the Sun angle. In one embodiment of the invention, the solar conical units are hollow, thereby permitting back side cooling to be facilitated. In one embodiment of the invention, the solar conical units can be solid.

The conical solar cell unit 2 may be considered to be a “Solar Cell Tower” which differs from the conventional “flat panel” configuration. The following non-limiting description explains a number of advantages and different embodiments of the solar cell tower configurations described herein. These explanations are exemplary and do not limit the solar cell tower configuration of this invention.

As noted above, a conical solar cell has a photo-responsive section in the form of a cone. The conical solar cell according to one embodiment of the invention may comprise for the one or more p-n junctions whereby light entering the semiconductor material through the n region and generates an electron-hole pair (“EHP”) in the material due to the photoelectric effect. The n region may be substantially thin while the depletion region thick. If the EHP is generated in the depletion region, the built-in electric field drifts the electron and hole apart resulting in a current though the device called a photocurrent. If the EHP is generated in the n or p regions, the electron and hole may drift in random directions and may or may not become part of the photocurrent.

With single junction solar cells, much of the energy of incident light is not converted into electricity. If an incident photon has less energy than the bandgap of the semiconductor material (i.e., the energy difference or range (in eV) between the top of the valence band and the bottom of the conduction band and is the amount of energy required to free an outer shell electron to a free state), the photon cannot be absorbed since there is not enough energy to excite an electron from the conduction band to the valence band; therefore, none of the light with less energy than the bandgap is used in the solar cell. If an incident photon has a higher energy than the bandgap, the excess energy will be converted into heat since the electron can only absorb the exact amount of energy required to move to the valence band.

Multi junction solar cells make better use of the solar spectrum by having multiple semiconductor layers with different bandgaps. Each layer may be made of a different material (usually a III-V semiconductor but may also be a II-VI semiconductor) and may absorb a different portion of the spectrum. Generally, the top layer provides the largest bandgap so that the most energetic photons are absorbed in this layer. Less energetic photons must pass through the top layer since they are not energetic enough to generate EHPs in the material. Each layer going from the top to the bottom may have a smaller bandgap than the previous layer; therefore, each layer may absorb photons having energies greater than the bandgap of that layer and less than the bandgap of a higher layer. One exemplary form of a multi junction solar cell may comprise three layers and may be generally termed as a triple-junction solar cell.

Performance of a solar cell (regardless of design) may be measured by several terms: short-circuit current (current of a solar cell when the negative and positive leads (top and bottom of cell) are connected with a short circuit); open-circuit voltage (voltage between top and bottom of a solar cell); power point (point on the current-voltage curve of a solar cell that generates the maximum amount of power for the device); fill factor (a value that describes how close the current-voltage curve of a solar cell resembles an ideal solar cell); quantum efficiency (number of EHPs that are created and collected divided by the number of incident photons); external quantum efficiency (EQE) (a function of the flux of photons reaching the photovoltaic medium); overall efficiency (percent of incident electromagnetic radiation that is converted to electrical power).

Regardless of the cell design, the goal is to convert all of the appropriate wavelengths of the solar spectrum without losing light which could otherwise generate an EHP and without losing the energy generated from the photoelectric conversion material 12 by other overall system losses. Yet, with the flat panel design, not all light of the appropriate wavelengths is absorbed, as some part of the light is diverted from the cell prior to entering the photoelectric conversion material or exits the photoelectric conversion material before being absorbed. Moreover, with solar conversion materials in general, overheating can cause a reduction in efficiency, requiring for the flat panel design (and especially if utilized in a concentrator configuration) an active cooling system to be used, else lower conversion efficiencies have to be tolerated.

In one embodiment of this invention, the solar cone units 2 are rotatable. Rotation of the solar cone units 2 is especially preferred in concentrator configurations as many photoelectric conversion materials are temperature sensitive and show decreased conversion efficiencies at higher operating temperatures. By rotating the cone units 2 along their longitudinal axis, the local temperature of the photoelectric conversion material facing the sun is moderated such that its temperature excursion is minimized, thereby improving the operating conversion efficiency.

Furthermore, light entering the photoelectric conversion material (i.e. the semiconductor material) through an n-type semiconductor region generates an electron-hole pair (“EHP”) in the material due to the photoelectric effect. Some light may be reflected as it enters the n-type semiconductor region despite the presence of anti-reflective (AR) coatings. The n region may be substantially thin as compared to a thicker depletion region of the p-n junction. If the EHP is generated in the depletion region, the built-in electric field drifts the electron and hole apart resulting in a current though the device called a photocurrent. If the EHP is generated in the n or p regions, the electron and hole may drift in random directions and may or may not become part of the photocurrent. If the thickness of the photoelectric conversion material is too thin, light of the appropriate wavelength to generate an EHP will pass through the solar cell without absorption. However, the making the thickness of the photoelectric conversion material thicker to absorb more of the light can lead to additional internal resistances costing overall efficiency which further leads to the heating problem noted above. Moreover, the solar spectrum contains wavelengths in the infrared which are not converted into EHPs but which can be absorbed in the photoelectric conversion material. Having “excess” of the photoelectric conversion material also adds to the heating problem.

In considering the conical solar cell unit 2, assume that photoelectric conversion material 12 disposed on the conical surface 10 is a higher index material than the air outside of the conical solar cell 2. With a flat panel design, light is incident substantially normal the flat panel with little if any refraction (bending) of the solar light rays. The light rays transit the nominal thickness of the photoelectric conversion material 12 except for those rays which are absorbed. The optical path length is merely the thickness t of the layer of photoelectric conversion material 12.

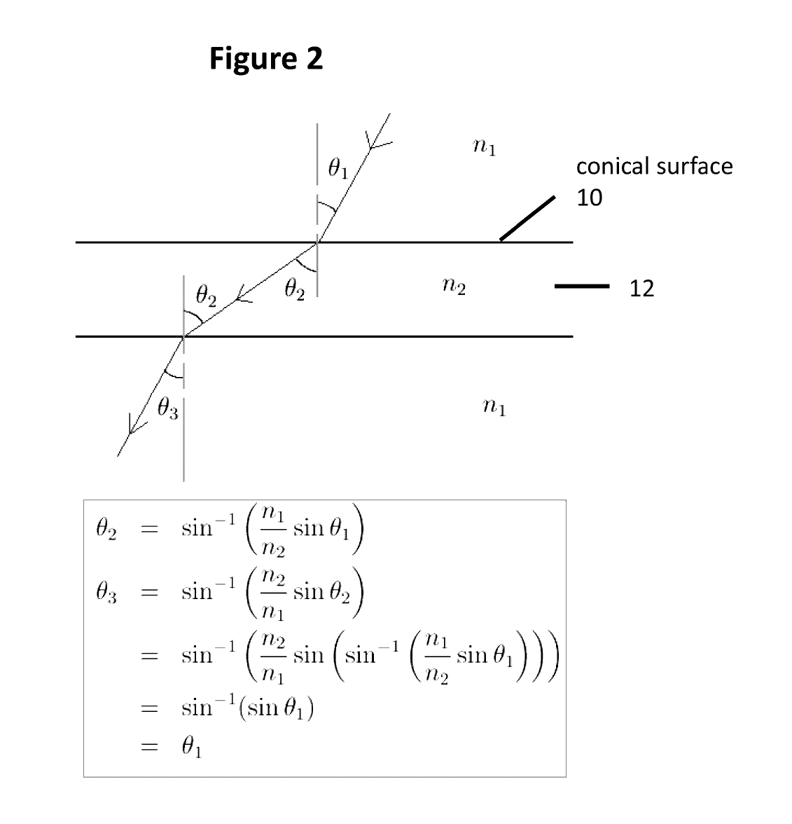

However, in the conical design, the incident solar light rays upon encountering the conical surface 10 of a different refractive index η are refracted in a direction away from normal as the rays enter into the photoelectric conversion material 12 because of the curvature of the cone. FIG. 2 is a reproduction of Snell's law illustrating the basic phenomena of light refraction. While for the sake of simplicity this drawing depicts linear interfaces (as for example along a longitudinally extending interface on the side of conical surface 10, similar principles hold for curved surfaces. The bending of the rays upon entering the photoelectric conversion material 12 of the Solar Cell Tower configuration means that the solar light rays ray now travel a longer optical path in the photoelectric conversion material 12 than the thickness t. The enhancement scales as the angle of refraction.

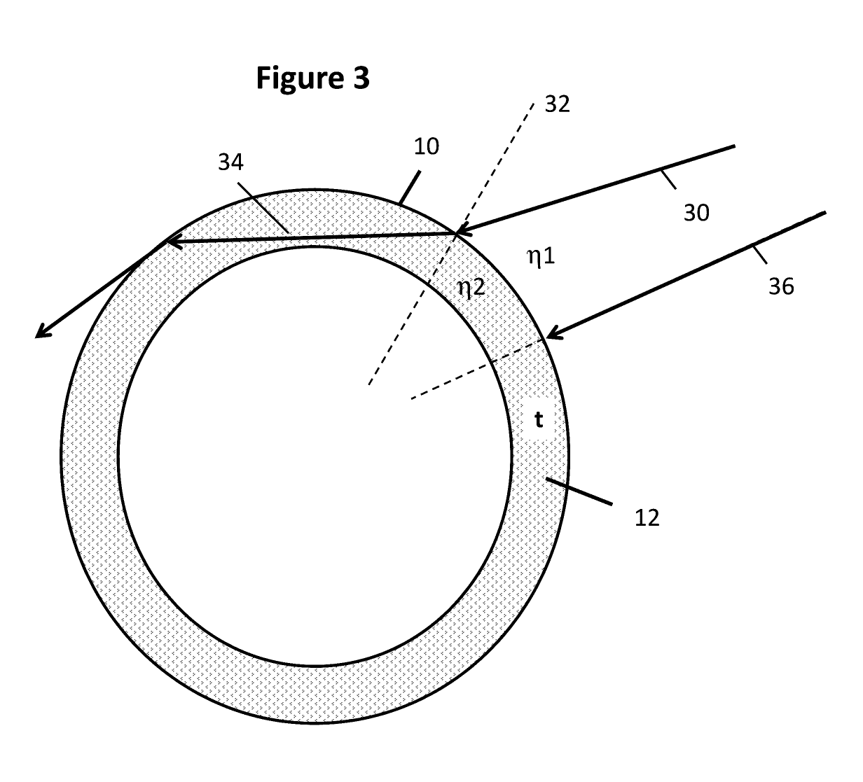

Assume, for the purpose of illustration, that the conical solar cell 2 in FIG. 1 has its conical surface 10 aligned to be normal to the sun's position in the sky. Nonetheless, light striking the conical surface 10 will encounter an optically contoured or curved surface representing that part of the conical surface 10 wrapping around to the other unexposed side of the cone. FIG. 3 shows a sectional view of a portion of the cone along the longitudinal axis of the cone at for example the mid-height of the cone. Solar ray 30 is incident conical surface 10 at an angle away from normal. A normal reference line 32 is shown at the point of contact of solar ray 30 to conical surface 10. The photoelectric conversion material 12 has an optical index η2 that is greater than air η1. As shown, the refracted ray 34 follows Snell's law and is bent (refracted) in the direction shown such that the refracted ray 34 transits a much greater optical distance than the thickness t.

Accordingly, for a same thickness of photoelectric conversion material 12 (with collection electrodes on each side) not shown, many of the solar photons transiting the photoelectric conversion material 12 in the conical solar cell 2 transit a longer effective distance through the photoelectric conversion material 12 than for solar photons 36 incident normal the photoelectric conversion material 12. This effect is dependent on the difference in index of refraction between air and that of the photoelectric conversion material 12. This effect is dependent on the geometric scale and size of the cone and the thickness of the photoelectric conversion material 12.

In one embodiment of the invention, thinner photoelectric conversion materials (having less internal resistance across the electrodes disposed on each side of the photoelectric conversion material 12) can be used to absorb the same quantity of solar photons as their thicker counterparts in the flat panel design but with less electrical loss, thereby increasing the solar efficiency.

Since the voltage output of a conventional cell is related to the bandgap of the photoelectric conversion material 12 (for silicon ˜1.1 eV), a large area footprint with many cells connected in series over relatively large distances is needed to generate a significant output voltage. (Otherwise, step-up devices have to be used in conjunction with the solar cells which themselves would contribute to power loss.) Here, the conical design permits more cell area per unit base area.

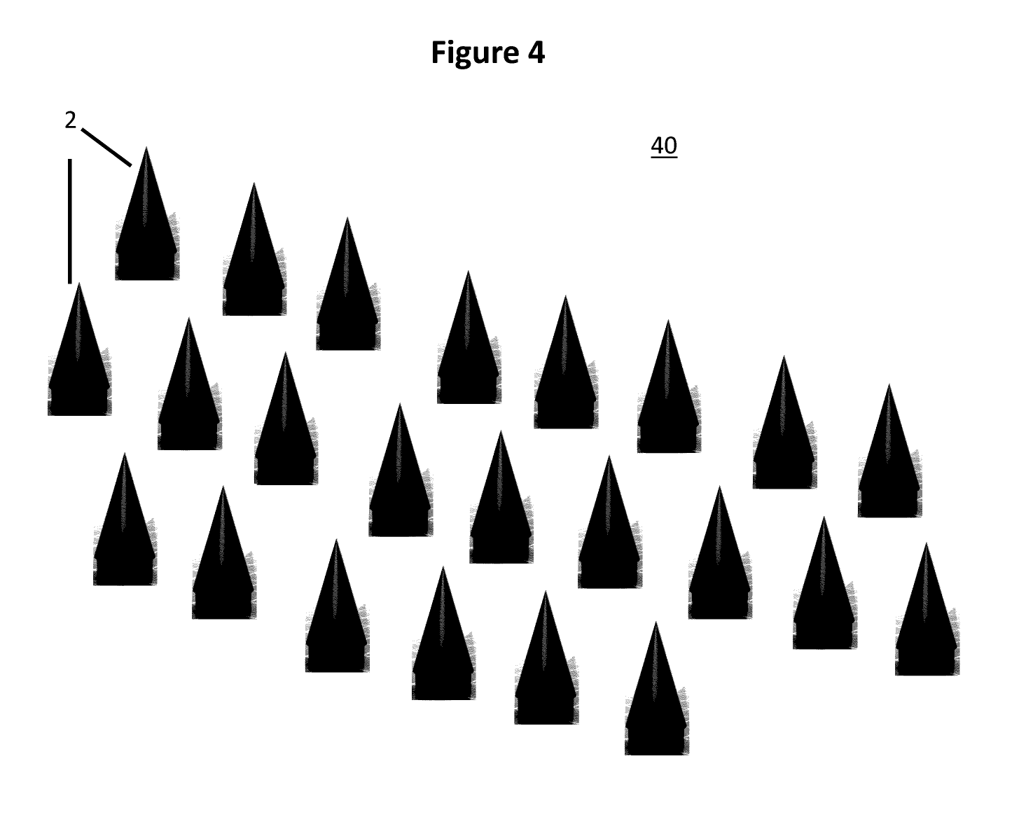

FIG. 4 is a schematic diagram showing a plurality of the cone units 2 forming a cell tower array 40. Assume that the mounting base has an area of 1 square meter (m²). If each cone unit 2 has a base diameter of 10 cm and a height of 10 cm, then the number of cones disposed on mounting base 20 in the 1 square meter is 100 units, and the total conical surface area is 25,400 cm² or 254 m². This represents an increase in the area of active material of 254%. If each cone unit has a base diameter of 10 cm and a height of 20 cm, then the number of cones in the 1 square meter is 100 units, and the total conical surface area is 40,200 cm² or 402 m². This represents an increase in area of active material of 400%. If the photoelectric conversion material 12 had a standard thickness, than the volume of photoelectric conversion material available in each square meter likewise would increase by these same factors. These numbers are indicative of the packing density improvement provided in one aspect of the invention.

Additionally, in a cell tower array 40 containing multiple cone units 2, any light “reflecting” away from one conical surface will likely be directed to another conical unit before exiting the cell tower array 40. This effect, like the “longer effective distance” also means that the conical units can capture solar photons normally discarded. In general, arrays of the conical solar cell units (and/or and lenses designed to focus solar energy) in various embodiments of the invention can trap, reflect and focus scattered solar light to maximize efficiency.

### Conical Solar Cell Unit Construction

In one embodiment of the invention, the conical photo-responsive section 4 is made with the conventional photoelectric conversion materials which may include the aforementioned crystalline silicon (c-Si), polycrystalline silicon, microcrystalline silicon, amorphous silicon (α-Si), gallium arsenide (GaAs), germanium (Ge), copper indium gallium diselenide (CIGS), Group IV compounds, and Group III-V compounds. Conventional doping and p-n junction configurations can be used.

In one embodiment of the invention, organic photovoltaic materials can also be used for the photoelectric conversion material 12. In an organic photovoltaic, small organic molecules forming a conjugated system are typically used and can be used here where carbon atoms covalently bond with alternating single and double bonds; in other words these are chemical reactions of hydrocarbons. These hydrocarbons' electrons pz orbitals delocalize and form a delocalized bonding π orbital with a π* antibonding orbital. The delocalized π orbital is the highest occupied molecular orbital (HOMO), and the π* orbital is the lowest unoccupied molecular orbital (LUMO). The voltage separation between HOMO and LUMO is considered the band gap of organic electronic materials. The band gap is typically in the range of 1-4 eV.

In one embodiment of the invention, the solar cone units 2 can be formed on steel sheet stock formed into the basic conical shape (or other closed section structure). Amorphous silicon material or the other materials noted above can be formed on the steel cones. Steel cones are commercially available through companies such as Chicago Metal Rolled Products, Chicago, Ill. 60632. Flexible solar cells on steel are available through Xunlight, Toledo, Ohio 43607. Xunlight products are bandgap-tuned triple junction thin-film silicon solar cells formed into lightweight and mechanically flexible photovoltaic modules.

In one embodiment of the invention, the solar cone units 2 can be formed on molded glass cones fabricated in a manner similar to that described in U.S. Pat. No. 2,882,784 (the entire contents of which are incorporated herein by reference), where cone shaped glass lenses were fabricated. In one embodiment of the invention, the solar cone units 2 can be formed on molded glass or resin cones fabricated in a manner similar to that described in U.S. Pat. No. 6,754,012 (the entire contents of which are incorporated herein by reference).

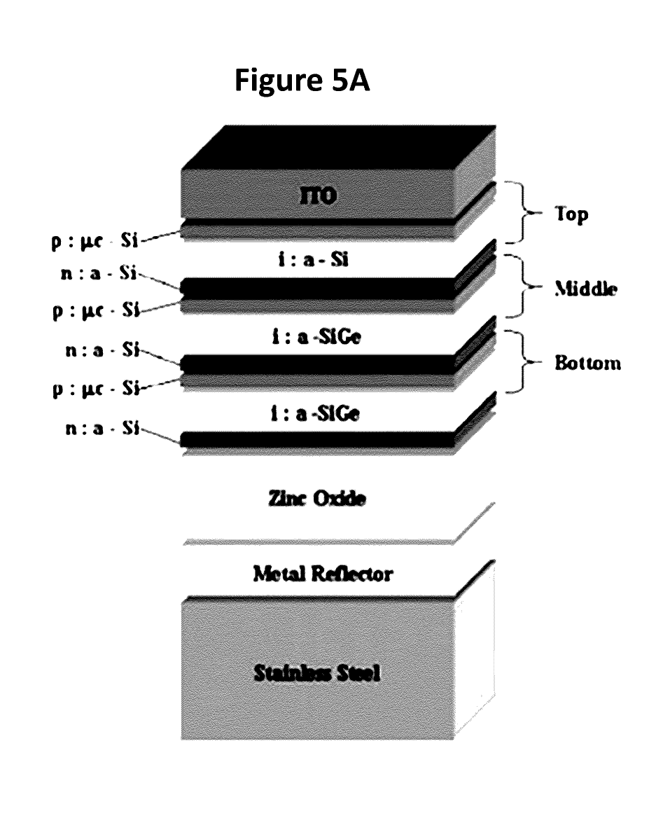

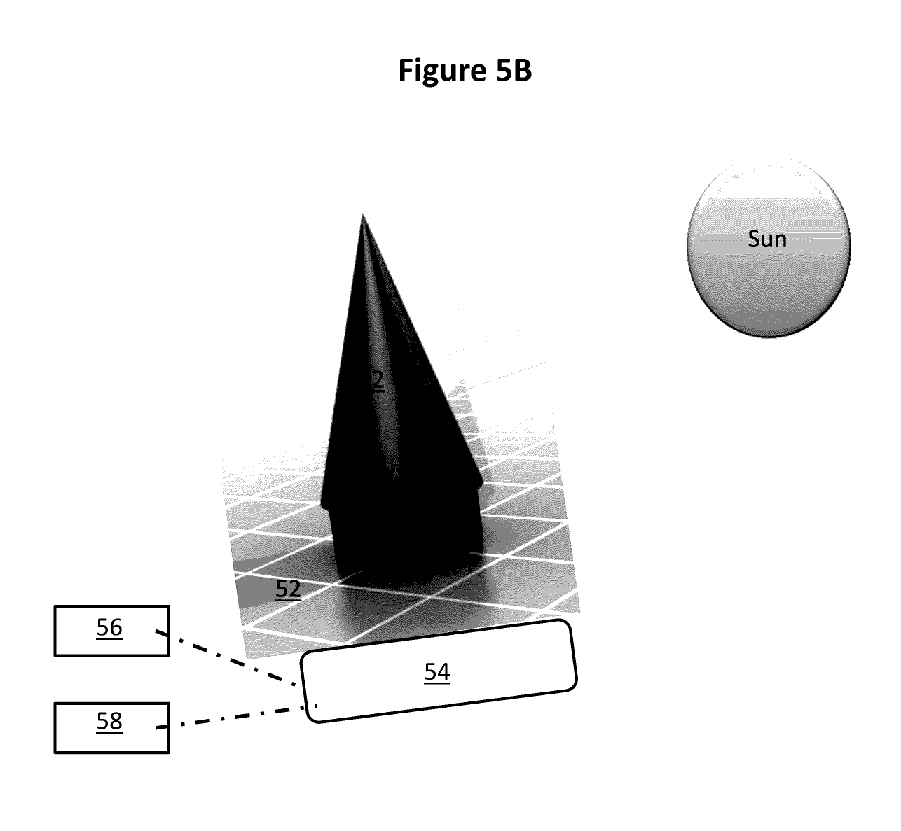

Once made, the cones are then subject to the deposition of electrodes 14, 16 and the photoelectric conversion material 12 and the interconnects there between. As used herein, the photoelectric conversion material 12 includes conversion materials (such as described above) as well as the necessary doping, junction structures, and/or materials combination to form a photovoltaic element. FIG. 5A is a schematic depicting an amorphous silicon multi junction structure on a stainless steel substrate. A detailed description of the elements shown in FIG. 5A is omitted here, but the structure includes a metal reflector layer deposited above the stainless steel substrate. On top of the metal reflector layer is a zinc oxide layer followed by a multi-junction tandem amorphous silicon/polycrystalline silicon and silicon germanium cell structure. On top of the multi junction cell structure is an indium tin oxide layer which serves as a transparent top contact. The structure shown in FIG. 5A is an exemplary structure of the photoelectric conversion material 12 useful in this invention.

In one embodiment of the invention, the mounting base 20 can include a reflective coating (such as aluminum). The reflective coating would help reflect solar photons escaping through the photoelectric conversion material 12 and escaping through base 6 of the cell back by reflecting such photons for a second transit through the photoelectric conversion material 12.

In one embodiment of the invention, exemplary conical solar cell units 2 according to embodiments of this invention may include a single-junction design or a multi junction design or an inverted multi-junction design. Exemplary systems may be terrestrial-based systems (e.g., AM 1.5, etc.) Further exemplary terrestrial-based systems may include one-sun systems and concentrator systems (5-1000 suns) which employ lenses and/or mirrors as a primary light collector.

In one embodiment of the invention, exemplary conical solar cell units 2 according to embodiments of this invention may include antireflection coatings such as those known in the art. For example, antireflection coatings of TiO₂ (refractive index n=2.3), Si₃N₄ (n=1.9), Al₂O₃ (n=1.8-1.9), SiO₂ (n=1.4-1.5), Ta₂O₅ (n=2.1-2.3), a-SiNₓ:H, and a-Si:C:H can be used to minimize reflection losses.

### Rotation and Alignment of the Solar Tower

In one embodiment of this invention, the solar cone units 2 are rotatable. Rotation of the solar cone units 2 is especially preferred in concentrator configurations as many photoelectric conversion materials are temperature sensitive and show decreased conversion efficiencies at higher operating temperatures. In this embodiment of the invention, a drive mechanism is provided which rotates the cone units 2 about the conical axis of the cone.

In one embodiment of this invention, the mounting base 20 is part of a tracking system 30. FIG. 5B is a schematic depicting the tracking of a solar cell tower with the sun. In this embodiment, for example, a “solar cell tower” including one or more of the conical solar cell units 2 works like a satellite tracking system which moves according to a tracking signal. Here, the solar cell tower by way of tracking control 54 would automatically adjust the inclination of base 52 to track the sun starting from the east (Sunrise) to West (Sunset) for example from 6:00 AM to 18:00 PM. Additionally, the tracking control 54 would move to track the position of the sun above the horizon. At sunset, the tracking control 54 could restore to the solar cell tower 2 to its sunrise position before powering down for the night.

The tracking control 54 would include a mechanism for elevating the mounting base 52 and/or a mechanism for changing the inclination of the mounting base 52 with respect to ground or other surface supporting the mounting base 52. A conventional hydraulic or mechanical jack could be controlled by tracking control 54 to adjustably vary the elevation angle of orientation of the mounting base 52 relative to a platform. The translation mechanisms and controls thereof are known in the art, as described in U.S. Pat. No. 4,398,053 (the entire contents of which are incorporated herein by reference) and in U.S. Pat. Appl. Publ. No. 20110017270 (the entire contents of which are incorporated herein by reference).

As noted above, tracking control 54 could simultaneously rotate the conical solar cell units and adjust a position of the mounting base 52 to track the Sun angle.

### Other Features

Environmental factors can cause degradation in the power output. FIG. 5B shows tracking control 54 in communication with a cleaning system 56 and a cooling system 58. In one embodiment of the invention, automatic cleaning and cooling systems for the photoresponsive materials can be employed. U.S. Pat. Appl. Publ. No. 20110094549 (the entire contents of which are incorporated herein by reference) describes a solar cell cleaning device useful in this invention. In one embodiment of the invention, the cleaning system 56 would include a frame, spraying device, an operating device, a cleaning devices for cleaning the solar units 2, and a controller for controlling the automatic cleaning system. The frame of the cleaning system would preferably enclose one or more of the solar units 2. The spraying device would includes a tank, a sprinkler mounted above for example base 52, and a pipe connected between the tank and the sprinkler. The tank would store cleaning fluid, such as a water/cleaning mixture. The controls would activate the sprinkle to sprinkle or flow the cleaning fluid from the tank onto the solar units 2 or a transparent protection cover above the solar units 2. The conical shape facilitates the expulsion of water and/or the cleaning and rinsing solutions as the liquid droplets do not have as much contact area to the curved surface.

As noted above, automatic cooling systems for the photoresponsive materials can also be employed especially in the solar cell concentrator configuration. With cooling system 58, a cooling fluid (water or air) in this embodiment would be circulated to be in contact with the base 6 or mounting base 52. In one embodiment of the invention, the solar conical units are hollow permitting the cooling fluid to circulate in that space.

Additionally, sails or other wind powered devices such as wind turbines can be used to permit wind power to provide auxiliary power to the solar cell platform, for example to power rotation of the mounting base 52 or the cleaning and cooling systems. Alternatively, a battery can be used to supply auxiliary power to the solar cell platform.

### Power Generation Method

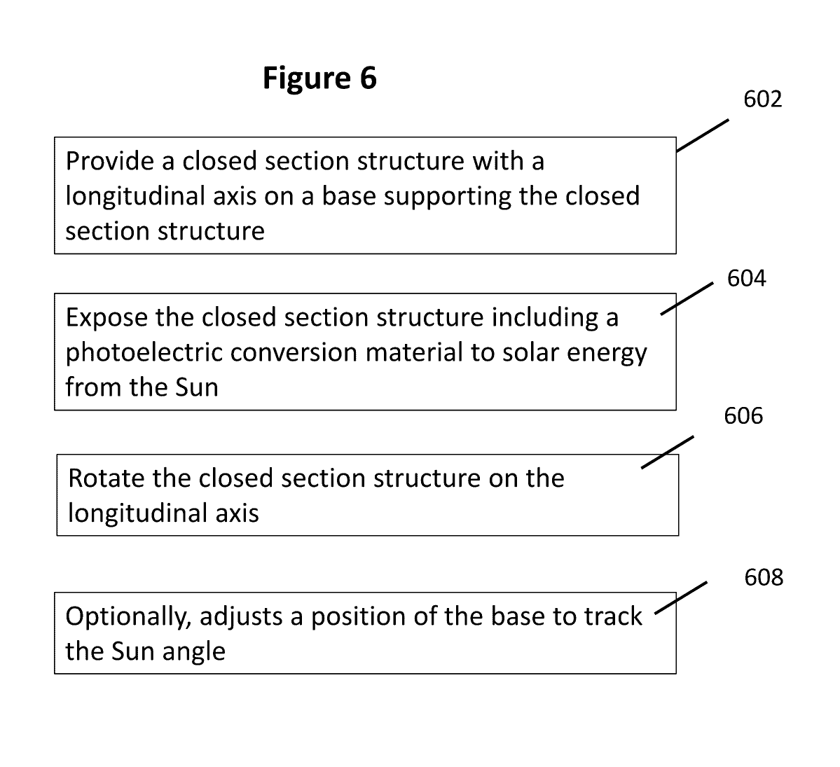

In one embodiment of the invention, there is provided a method of producing photovoltaic power from the devices described above. This method is depicted in FIG. 6, a flow chart depiction of this method. The method in step element 602 provides a closed section structure with a longitudinal axis on a base supporting the closed section structure. The method in step element 604 exposes the closed section including a photoelectric conversion material to an energy source (e.g., solar energy from the Sun). The method in step element 606 rotated the closed section structure on its longitudinal axis. Optionally, the method in step element 608 adjusts a position of the base to track the energy source (i.e., the Sun angle).

### Computerized Control

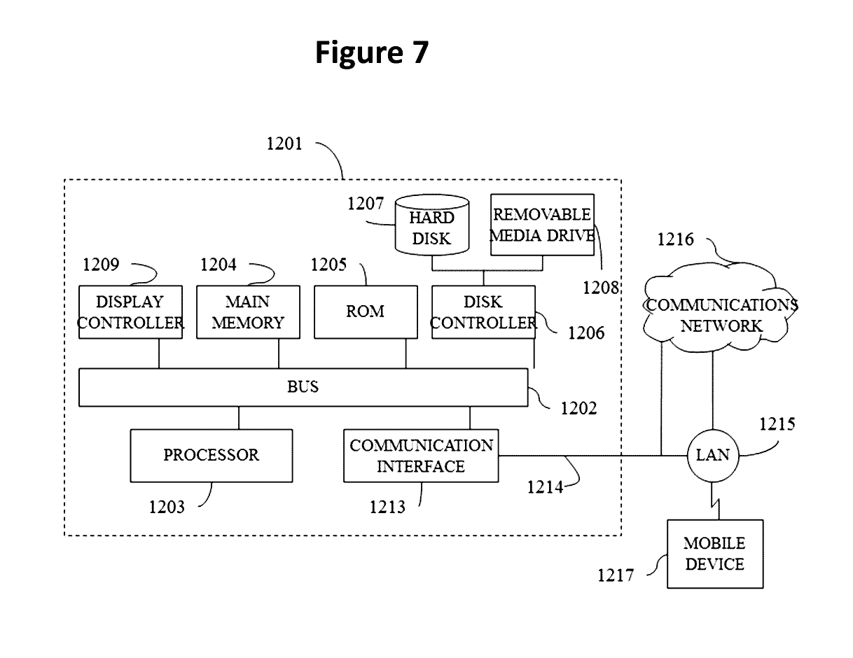

FIG. 7 is a schematic depicting a computer system 1201 for implementing various embodiments of the invention including that of operating the tracking system of FIG. 5B or the automatic cleaning and cooling systems noted above.

The computer system 1201 for example may be used as the tracking control 54 to control the tracking of mounting base 52 (or to perform any or all of the other functions described above). The computer system 1201 includes a bus 1202 or other communication mechanism for communicating information, and a processor 1203 coupled with the bus 1202 for processing the information. The computer system 1201 also includes a main memory 1204, such as a random access memory (RAM) or other dynamic storage device (e.g., dynamic RAM (DRAM), static RAM (SRAM), and synchronous DRAM (SDRAM)), coupled to the bus 1202 for storing information and instructions to be executed by processor 1203. In addition, the main memory 1204 may be used for storing temporary variables or other intermediate information during the execution of instructions by the processor 1203. The computer system 1201 further includes a read only memory (ROM) 1205 or other static storage device (e.g., programmable read only memory (PROM), erasable PROM (EPROM), and electrically erasable PROM (EEPROM)) coupled to the bus 1202 for storing static information and instructions for the processor 1203.

The computer system 1201 also includes a disk controller 1206 coupled to the bus 1202 to control one or more storage devices for storing information and instructions, such as a magnetic hard disk 1207, and a removable media drive 1208 (e.g., floppy disk drive, read-only compact disc drive, read/write compact disc drive, compact disc jukebox, tape drive, and removable magneto-optical drive). The storage devices may be added to the computer system 1201 using an appropriate device interface (e.g., small computer system interface (SCSI), integrated device electronics (IDE), enhanced-IDE (E-IDE), direct memory access (DMA), or ultra-DMA).

The computer system 1201 may also include special purpose logic devices (e.g., application specific integrated circuits (ASICs)) or configurable logic devices (e.g., simple programmable logic devices (SPLDs), complex programmable logic devices (CPLDs), and field programmable gate arrays (FPGAs)).

The computer system 1201 may also include a display controller 1209 coupled to the bus 1202 to control a display, such as a cathode ray tube (CRT), for displaying information to a computer user. The computer system includes input devices, such as a keyboard and a pointing device, for interacting with a computer user and providing information to the processor 1203. The pointing device, for example, may be a mouse, a trackball, or a pointing stick for communicating direction information and command selections to the processor 1203 and for controlling cursor movement on the display.

The computer system 1201 performs the tracking or other functions of the invention (such as for example those described in relation to cleaning or cooling) in response to the processor 1203 executing one or more sequences of one or more instructions contained in a memory, such as the main memory 1204. Such instructions may be read into the main memory 1204 from another computer readable medium, such as a hard disk 1207 or a removable media drive 1208. One or more processors in a multi-processing arrangement may also be employed to execute the sequences of instructions contained in main memory 1204. In alternative embodiments, hard-wired circuitry may be used in place of or in combination with software instructions. Thus, embodiments are not limited to any specific combination of hardware circuitry and software.

As stated above, the computer system 1201 includes at least one computer readable medium or memory for holding instructions programmed according to the teachings of the invention and for containing data structures, tables, records, or other data described herein. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the invention includes software for controlling the computer system 1201, for driving a device or devices for implementing the invention, and for enabling the computer system 1201 to interact with a human user who for example may be monitoring the solar cell platform performance. Such software may include, but is not limited to, device drivers, operating systems, development tools, and applications software. Such computer readable media further includes the computer program product of the invention for performing all or a portion (if processing is distributed) of the processing performed in implementing the invention.

A computer readable medium may take many forms, including but not limited to, non-volatile media, volatile media, and transmission media. Non-volatile media includes, for example, optical, magnetic disks, and magneto-optical disks, such as the hard disk 1207 or the removable media drive 1208. Volatile media includes dynamic memory, such as the main memory 1204. Transmission media includes coaxial cables, copper wire and fiber optics, including the wires that make up the bus 1202. Transmission media also may also take the form of acoustic or light waves, such as those generated during radio wave and infrared data communications.

The computer system 1201 can also include a communication interface 1213 coupled to the bus 1202. The communication interface 1213 provides a two-way data communication coupling to a network link 1214 that is connected to, for example, a local area network (LAN) 1215, or to another communications network 1216 such as the Internet. These local and non-local communications permit the solar cell towers to monitor information related to the sun angle or information related to the power grid to which an individual cell tower is connected. For example, the communication interface 1213 may be a network interface card to attach to any packet switched LAN. As another example, the communication interface 1213 may be an asymmetrical digital subscriber line (ADSL) card, an integrated services digital network (ISDN) card or a modem to provide a data communication connection to a corresponding type of communications line. Wireless links may also be implemented. In any such implementation, the communication interface 1213 sends and receives electrical, electromagnetic or optical signals that carry digital data streams representing various types of information.

The network link 1214 typically provides data communication through one or more networks to other data devices. For example, the network link 1214 may provide a connection to another computer through a local network 1215 (e.g., a LAN) or through equipment operated by a service provider, which provides communication services through a communications network 1216. In one embodiment, this provides the invention the capability to have multiple of the above described solar cell towers networked together and in communication with each other and a power grid authority for purposes load control and power matching to the grid which the towers service. The local network 1214 and the communications network 1216 use, for example, electrical, electromagnetic, or optical signals that carry digital data streams, and the associated physical layer (e.g., CAT 5 cable, coaxial cable, optical fiber, etc). The signals through the various networks and the signals on the network link 1214 and through the communication interface 1213, which carry the digital data to and from the computer system 1201 may be implemented in baseband signals, or carrier wave based signals. The baseband signals convey the digital data as unmodulated electrical pulses that are descriptive of a stream of digital data bits, where the term “bits” is to be construed broadly to mean symbol, where each symbol conveys at least one or more information bits.

### Generalized Statements of the Invention

The following numbered statements provide a general description of the invention and are not intended to limit the appended claims.

Statement 1. A solar cell, comprising:

a photo-responsive section in the form of a closed section structure (e.g., a cone having a base, an apex, and a conical surface);

said photo-responsive section having a photoelectric conversion material disposed on the closed section (e.g. the conical surface of the cone), said photoelectric conversion material configured to absorb light and produce an electrical current,

a first electrode connected to the photoelectric conversion material; and

a second electrode connected to the photoelectric conversion material whereby photovoltaic energy is extractable from the photoelectric conversion material.

Statement 2. The cell of statement 1, wherein the cone has a diameter at the base which is less than or equal to a height of the cone as measured from a center point of the base to the apex of the cone.

Statement 3. The cell of statement 1, further comprising a mounting base on which the closed section structure (e.g., the cone) is mounted.

Statement 4. The cell of statement 3, wherein the mounting base is attached to a drive mechanism that rotates the closed section structure (e.g., the cone) about a longitudinal axis thereof.

Statement 5. The cell of statement 3, wherein the mounting base is position-adjustable.

Statement 6. The cell of statement 5, wherein the mounting base is attached to a tracking mechanism that aligns the surface of the closed section structure (e.g., the cone) perpendicularly with sunlight.

Statement 7. The cell of statement 5, wherein the mounting base is attached to a tracking mechanism that aligns the apex of the closed section structure (e.g., the cone) coincident with a position of the Sun.

Statement 8. The cell of statement 1, wherein the photoelectric conversion material includes an inorganic photovoltaic material.

Statement 9. The cell of statement 8, wherein the inorganic photovoltaic material includes at least one of crystalline silicon (c-Si), polycrystalline silicon, microcrystalline silicon, amorphous silicon (α-Si), gallium arsenide (GaAs), germanium (Ge), copper indium gallium diselenide (CIGS), Group IV compounds, and Group III-V compounds.

Statement 10. The cell of statement 1, wherein the photoelectric conversion material includes an organic photovoltaic material.

Statement 11. The cell of statement 1, wherein the cone comprises a rolled sheet or a molded glass or resin product.

Statement 12. The cell of statement 1, wherein the photo-responsive section includes an anti-reflective coating

Statement 13. The cell of statement 1, wherein the photoelectric conversion material covers at least 70% or at least 80% or at least 90% or at least 95% of the external (e.g., conical) surface of the closed section structure (e.g., of the cone).

Statement 14. A solar cell platform comprising:

a base supporting one or more of the solar cells of statement 1; and

a controller programmed to at least one of 1) track an instantaneous position of the Sun in the sky, 2) rotate the conical solar cell(s) each about a longitudinal axis thereof, and 3) adjust an inclination of the base to align the base with the instantaneous position of the Sun.

Statement 15. The platform of statement 14, further comprising a cleaning system which cleans the conical solar cells or a transparent cover over the conical solar cells.

Statement 16. The platform of statement 14, further comprising a cooling system which provides a coolant to the conical solar cells.

Statement 17. The platform of statement 14, further comprising at least one of wind powered source and a battery to provide auxiliary power to the solar cell platform.

Statement 18. The platform of statement 14, wherein said controller is in communication with other platforms for monitoring of power generation and solar tracking of the other platforms.

Statement 19. The platform of statement 14, wherein said controller is in communication with a power grid authority.

Statement 20. A method of producing photovoltaic power comprising: providing a closed section structure with a longitudinal axis on a base supporting the closed section structure; exposing the closed section structure including a photoelectric conversion material to an energy source (e.g., solar energy from the Sun); rotating the closed section structure on its longitudinal axis; and optionally, adjusting a position of the base to track the energy source (i.e., the Sun angle).

Numerous modifications and variations of the present invention are possible in light of the above teachings. It is therefore to be understood that within the scope of the appended claims, the invention may be practiced otherwise than as specifically described herein.

1. A conical solar cell, comprising:
a photo-responsive section in the form of a cone having a base, an apex, and a conical surface;
said photo-responsive section having a photoelectric conversion material disposed on the conical surface of the cone, said photoelectric conversion material configured to absorb light and produce an electrical current,
a first electrode connected to the photoelectric conversion material; and
a second electrode connected to the photoelectric conversion material whereby photovoltaic energy is extractable from the photoelectric conversion material.

2. The cell of claim 1, wherein the cone has a diameter at the base which is less than a height of the cone as measured from a center point of the base to the apex of the cone.

3. The cell of claim 1, further comprising a mounting base on which the cone is mounted.

4. The cell of claim 3, wherein the mounting base is attached to a drive mechanism that rotates the cone about a longitudinal axis thereof.

5. The cell of claim 3, wherein the mounting base is position-adjustable.

6. The cell of claim 5, wherein the mounting base is attached to a tracking mechanism that aligns the surface of the cone perpendicularly with sunlight.

7. The cell of claim 5, wherein the mounting base is attached to a tracking mechanism that aligns the apex of the cone coincident with a position of the Sun.

8. The cell of claim 1, wherein the photoelectric conversion material includes an inorganic photovoltaic material.

9. The cell of claim 8, wherein the inorganic photovoltaic material includes at least one of crystalline silicon (c-Si), polycrystalline silicon, microcrystalline silicon, amorphous silicon (α-Si), gallium arsenide (GaAs), germanium (Ge), copper indium gallium diselenide (CIGS), Group IV compounds, and Group III-V compounds.

10. The cell of claim 1, wherein the photoelectric conversion material includes an organic photovoltaic material.

11. The cell of claim 1, wherein the cone comprises a rolled sheet or a molded glass or resin product.

12. The cell of claim 1, wherein the photo-responsive section includes an anti-reflective coating

13. The cell of claim 1, wherein the photoelectric conversion material covers at least 70% of the conical surface.

14. A solar cell platform comprising:
a base supporting one or more of the conical solar cells of claim 1; and
a controller programmed to at least one of 1) track an instantaneous position of the Sun in the sky, 2) rotate the conical solar cells each about a longitudinal axis thereof, and 3) adjust an inclination of the base to align the base with the instantaneous position of the Sun.

15. The platform of claim 14, further comprising a cleaning system which cleans the conical solar cells or a transparent cover over the conical solar cells.

16. The platform of claim 14, further comprising a cooling system which provides a coolant to the conical solar cells.

17. The platform of claim 14, further comprising at least one of a wind powered source and a battery to provide auxiliary power to the solar cell platform.

18. The platform of claim 14, wherein said controller is in communication with other platforms for monitoring of power generation and solar tracking of the other platforms.

19. The platform of claim 14, wherein said controller is in communication with a power grid authority.

20. A method of producing photovoltaic power, comprising:
providing a closed section structure with a longitudinal axis on a base supporting the closed section structure;
exposing the closed section structure including a photoelectric conversion material to solar energy from the Sun;
rotating the closed section structure on said longitudinal axis; and
optionally, adjusting a position of the base to track the Sun angle.
